(19) United States
(12) Patent Application Publication
(10) Pub. No.: US 2025/0020713 A1
(43) Pub. Date: Jan. 16, 2025

(54) MARGIN TESTER MEASUREMENT USING MACHINE LEARNING

(71) Applicant: Tektronix, Inc., Beaverton, OR (US)

(72) Inventors: John J. Pickerd, Hillsboro, OR (US); Sam J. Strickling, Cypress, TX (US); Kan Tan, Portland, OR (US)

(21) Appl. No.: 18/769,683

(22) Filed: Jul. 11, 2024

Related U.S. Application Data
(60) Provisional application No. 63/513,849, filed on Jul. 14, 2023.
(60) Provisional application No. 63/514,518, filed on Jul. 19, 2023.

(51) Int. Cl. G01R 31/28

(52) U.S. Cl. CPC G01R 31/2834

(57) ABSTRACT

A margin tester includes one or more ports to allow the margin tester to connect to a device under test (DUT), a memory, the memory containing a margin tester signature, a transmitter, a receiver to receive signals from the DUT, one or more processors configured to execute code that causes the one or more processors to: receive multiple signals from the receiver through the one or more ports, generate a performance indicator from the multiple signals, send the performance indicator and the margin tester signature to one or more machine learning networks, and receiving a result from the one or more machine learning networks containing a performance measurement prediction for the DUT.

### CROSS-REFERENCE TO RELATED APPLICATIONS

This disclosure is a non-provisional of and claims benefit from U.S. Provisional Application No. 63/513,849, titled “MARGIN TESTER MEASUREMENT USING MACHINE LEARNING,” filed on Jul. 14, 2023, and U.S. Provisional Application No. 63/514,518, titled “MARGIN TESTER TRANSLATION FOR PASS/FAIL RESULT USING MACHINE LEARNING,” filed on Jul. 19, 2023, the disclosure of both of which are incorporated herein by reference in their entirety.

### TECHNICAL FIELD

This disclosure relates to test and measurement instruments, and more particularly to using machine learning to better correlate measurements made by different test and measurement instruments.

### BACKGROUND

The Tektronix Margin Tester (TMT) has both transmitters and receivers built in that currently support PCIE Gen3 and Gen4 standards. See https://www.tek.com/en/products/pciemargintester.

The traditional method to test the DUT transmitter uses a real-time (RT) oscilloscope to acquire waveform, and then measurement software such as SigTest, Seasim and DPOJET, (see https://www.tek.com/en/datasheet/jitter-noise-and-eye-diagram-analysis-solution), to generate eye diagrams, BER (bit error ratio) contour plots, and measurements such as eye height, eye width, receiver DFE (decision feedback equalizer) tap values, and CTLE (continuous time linear equalizer) gains. The traditional method to test the DUT receiver uses a BERT (bit error ratio tester) to generate signals with the desired stress.

The TMT can test all PCIE (Peripheral Component Interface Express) channels simultaneously, as many as 16 channels. This approach has much higher throughput than the traditional way using an RT scope that typically only has four channels. The transmitter portion of the TMT can create various stress signals used as the signal source for DUT receiver testing. The TMT can generate signals at all channels simultaneously, up to 16 channels, much higher than the BERT. This enables higher throughput.

However, measurement results for the same DUT may vary from one particular TMT instrument to another particular TMT instrument, and the measurement results from a TMT instrument may not match the measurement results using the traditional method with the real-time oscilloscope and the BERT. Embodiments of this disclosure generally include machine-learning-based methods that reduce these instrument-to-instrument mismatches.

### BRIEF DESCRIPTION OF THE DRAWINGS

FIG. 1 shows an embodiment of a setup for testing a device under test (DUT) using a margin tester.

FIG. 2 shows an example of BER contour scan result on a margin tester.

FIG. 3 shows an embodiment of a setup for training a machine learning network for testing DUTs using a margin tester.

FIG. 4 shows an embodiment of training data for a neural network for a transmitter.

FIG. 5 shows an embodiment of a setup for runtime operation of a margin tester testing a DUT using a machine learning network.

FIG. 6 shows an embodiment of runtime data for testing a DUT.

FIG. 7 shows an embodiment of a training set up for training a neural network for receiver testing.

FIG. 8 shows an embodiment of a runtime setup for receiver testing using a neural network.

FIG. 9 shows an embodiment of a runtime setup for receiver testing using a calibrated TMT receiver with a neural network.

### DESCRIPTION

The embodiments here provide solutions to issues with mismatches between different margin testers and can speed up the testing process for transmitter and receiver devices, such as those used in PCIE devices. The use of a machine learning neural network reduces the time needed to test a device under test (DUT). Providing the neural network with a “signature” of the margin tester being used for testing allows the neural network to adjust any measurements made by the margin tester to adapt for that particular margin tester.

Currently, Tektronix remains the sole provider of margin testers. The following discussion refers to the margin tester as a “Tektronix Margin Tester” (TMT), with the understanding that other margin testers from other manufacturers that may become available have similar characteristics. The claims set out below will cover those margin testers that have the same characteristics and capabilities as the one discussed here, including supporting current and future standards, such as PCIE5 and PCIE6, and standards other than PCIE.

The discussion below applies to testing transmitters and receivers. No limitation to those particular kinds of DUTs is intended, nor should it be inferred. The DUT may comprise a different type of device that the TMT may have the capability of testing. Further, while the transmitters and receivers being used by TMT for testing may reside on a TMT, either the same one or on two different devices, no limitation to those transmitters or receivers is intended nor should any be inferred.

Prior to the advent of the TMT, transmitters (Tx) and receivers (Rx) had more complicated testing procedures using more, and typically more expensive, equipment. In receiver (Rx) testing, a BERT output signal undergoes calibration using an oscilloscope (scope). After the BERT output signal gets calibrated, the BERT is connected to the DUT, (Rx). The BERT receives the loop-back signal from the DUT to get the BER count, which does not use the scope. Rx testing generally involves a target stress level of the signal from transmitter in the TMT. The TMT has the ability to provide various stress levels that allow the TMT transmitter to test receivers. For Tx testing the scope with analysis software may make the pass-fail prediction to use as label for neural network training, as well as measurements as will be discussed in more detail later. The scope plus analysis software will make up the reference system with which the translator will look at margin tester BER data contours and make the pass-fail translation prediction, and/or various types of measurements as will be discussed in more detail later. The OptaML™ analysis software comprises an embodiment of the analysis software.

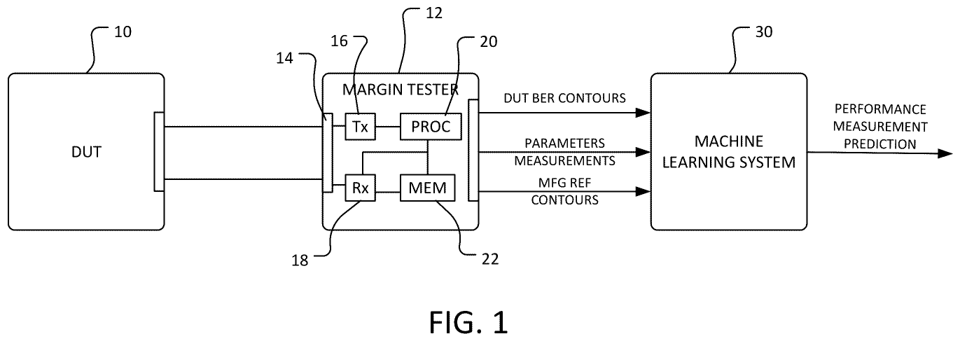

FIG. 1 shows an overall test setup using a TMT 12 to test the DUT 10. The TMT has one or more ports such as 14 to allow the TMT to send and receive signals from the DUT 10. As mentioned above, the TMT can test multiple channels at once, such as 16 channels. The connection between the DUT and the TMT may comprise a ribbon cable that has 16 or more connections to the TMT. The TMT has a transmitter 16 that allows the TMT to transmit test signals to the DUT, and a receiver 18 that allows the TMT to receive signals. The TMT will also have one or more processors 20 and a memory 22. The one or more processors may access the machine learning system 30 on an external device, or, as will be discussed below, the machine learning network may reside on the TMT.

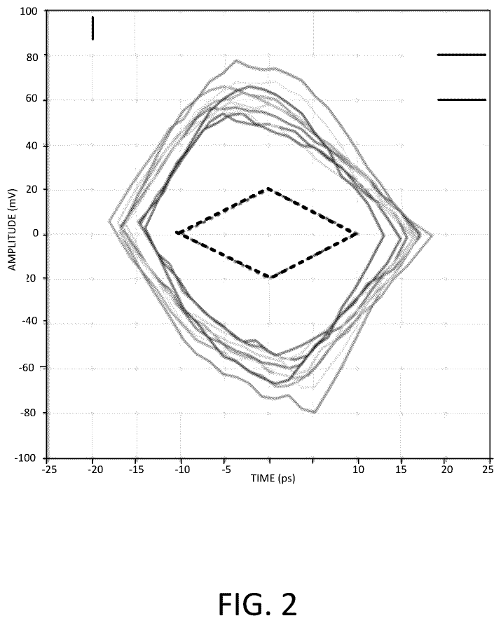

In one embodiment, the TMT receives signals transmitted from the DUT, and the TMT generates a set of BER contours for various BER levels for each channel. FIG. 2 shows an example of a set of BER contours generated by the TMT using the data from one of the 16 lanes on the DUT. Each contour line from each channel may be represented by a single image. This would result in 16 times however many contour vectors are used. The contour of FIG. 2 shows ten contours for 10 BER levels for one channel, so the resulting array would be a 10×16 array of individual contour lines. The machine learning system could receive this array of images for one DUT as input, or it could receive other formats, such as an image for each channel, an image for each DUT contour across all channels, etc. The image format used in runtime must match the image format used in training the neural network. Additionally, the input images may include other types of data.

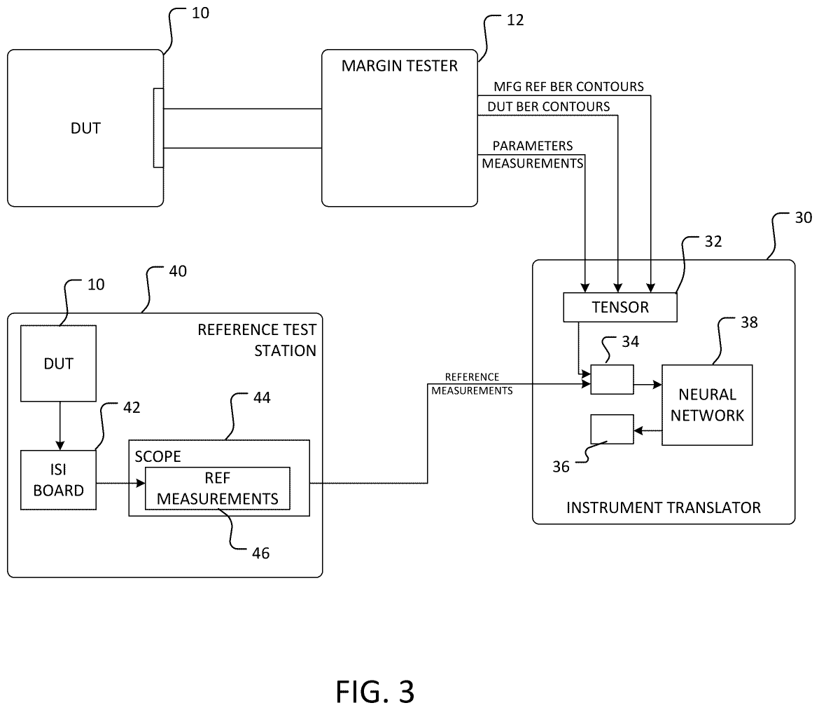

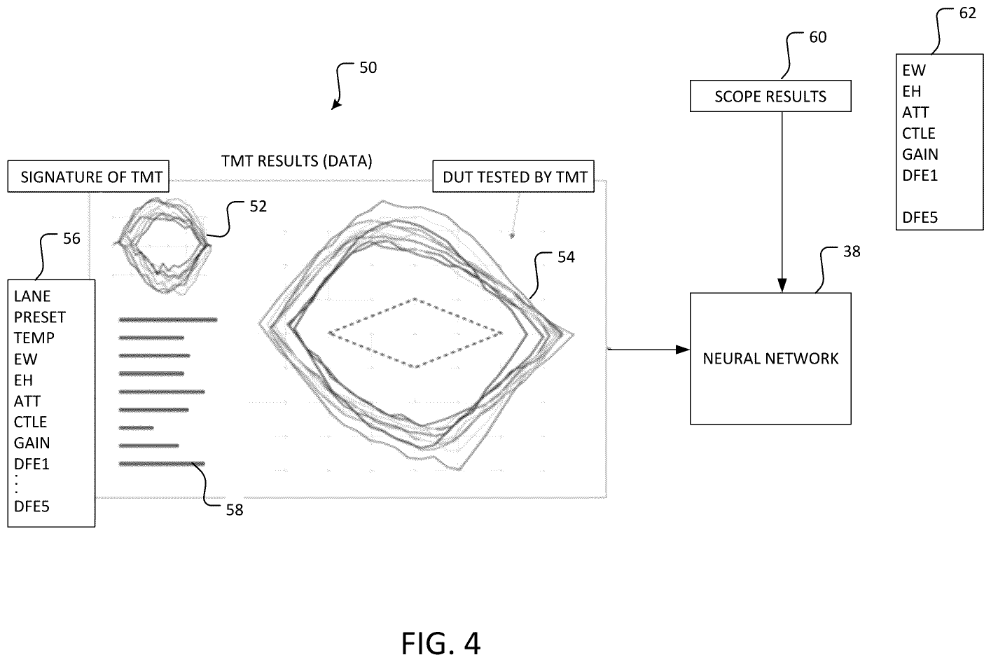

FIG. 3 shows an embodiment of a test setup for training the machine learning network 38 within the machine learning system 30. To simplify the drawings, the TMT 12 does not show its internal components with the understanding that TMT has the components shown in FIG. 1. During training, the TMT will send DUT BER contours received from the DUT, parameters, and measurements, discussed in more detail relative to FIG. 4, and the manufacturing reference BER contours (MFG REF BER contours) to the machine learning system 30, referred to here an instrument translator. The manufacturing reference BER contours acts as a “signature” of the TMT. As discussed above, the measurements and performance vary from TMT to TMT. This allows the machine learning system 30 to account for the measurements of the TMT.

The development of the TMT signature may take many forms. The TMTs do not have a way to calibrate them to make them more consistent. In one embodiment, the process uses a “golden” reference DUT to connect to the TMT that produces a set of contours, such as that in FIG. 2, for the reference DUT. The TMT then saves the resulting contours as the signature of the TMT. In one embodiment, the signature contours may be placed in one of the color channels of the input image different from the DUT BER contour data.

The machine learning system 30 as shown includes the neural network 38, and tensor builder 32. These components may reside in a separate computing device, or in the cloud, or may reside on TMT 12. The tensor builder 32 takes the input data and constructs a tensor image for input to the neural network. The input image may have three color channels, RGB, and one color channel may contain the TMT signature, as discussed above. U.S. patent application Ser. No. 17/747,954 “SHORT PATTERN WAVEFORM DATABASE BASED MACHINE LEARNING,” filed May 21, 2021, can provide more information about tensors, and is incorporated herein in its entirety.

The tensor input received from tensor builder 32 may undergo normalization at 34. While not used in the training environment of FIG. 3, the output of the neural network will undergo de-normalization at 36. The neural network receives the input data from the DUT, the TMT signature and any measurements made by the TMT. The tensor builder 32 may include the measurements as bar graphs, pie graphs, as well as many others, in the tensor image. These may include many different types of measurements, discussed relative to FIG. 4, and may include other information, such as the PCIE standard under which the transmitter is operating.

During training, the neural network 38 also receives reference data from a reference test station 40. The reference test station is also connected to the DUT 10, shown in repeat for drawing simplification. A variable ISI (intersymbol interference) board 42 resides between the DUT Tx output and the oscilloscope, or ‘scope,’ 44. ISI 42 can normally use multiple channels. In one embodiment, TMT 12 only uses one worst case channel matching the margin tester one as closely as possible, so the ISI 42 would only use one channel. This minimizes the amount of training required. The scope 44 receives the waveforms of the 16 lanes and measures them using some test measurement software, such as SigTest, DPOJET, PAM4, among many others, and then provides those measurements 46 to the neural network for association with the tensor data from the TMT.

FIG. 4 shows an example of a training input 50 to the neural network. The training input includes the TMT signature 52, and the contours 54 of the DUT undergoing testing as BER contours. Additional information 56 may also be included. This may include the lane, presets, temperature, measurements such as eye width (EW), eye height (EH), attenuation (ATT), settings for continuous time linear equalizers (CTLE), gain, and any decision feedback equalizers (DFE), among many others. The scope measurement reference results, following the same measurements made by the TMT, 62, are also input to the neural network 38. The neural network then associates that DUT and its signature, and the TMT measurements with the reference measurements.

One should note that in this particular embodiment, the DUT contours are used as a performance indicator of the DUT. In other margin testers, or in future embodiments of margin testers, a different type of performance indicator may be used. Similarly, as will be discussed below during runtime, the neural network provides a result that contains one or more performance measurement predictions for the DUT.

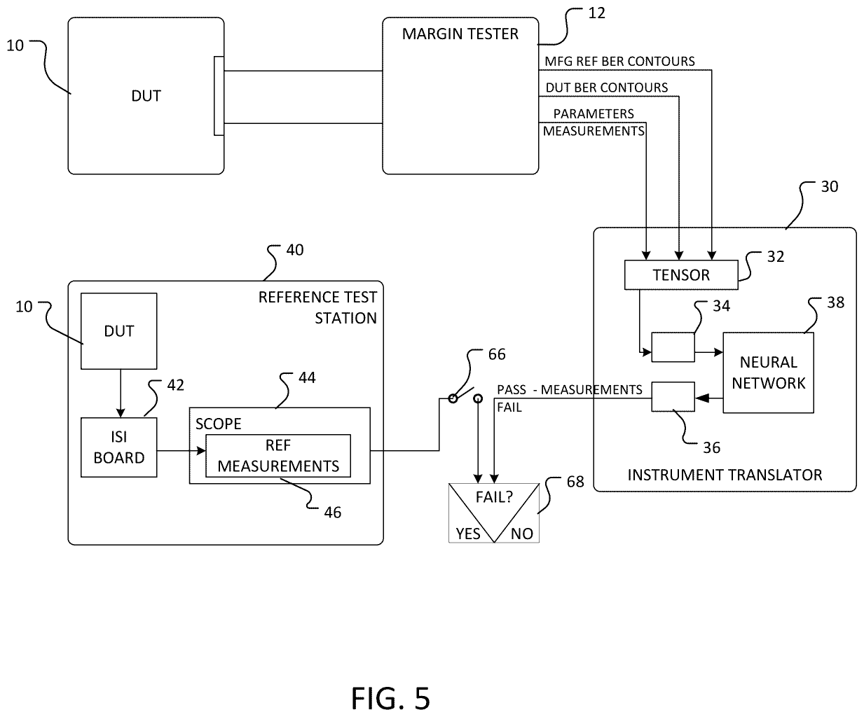

FIG. 5 shows an embodiment of the testing system during runtime. FIG. 5 shows the same components as FIG. 3, but other setups may also exist. In this embodiment of the runtime environment, the output data from the TMT is used to provide estimates of measurements, a pass/fail indicator, or both, for the DUT. As mentioned above, the output of the neural network 38 may undergo de-normalization at 36. Normalization converts the output of the tensor builder 32 to a range of values from −1 to +1. The output of the neural network is then converted back to from that range to an expected range for the measurements in general. In one embodiment, the measurement value, or a general pass/fail indicator, may be provided to a decision block 68. If the DUT did not pass, or if the measurement is out of range, the user would have the option of taking the measurement using reference station 40, enabled by switch 66. In another embodiment, that portion would not be included, and the user would just be presented with the various measurement results.

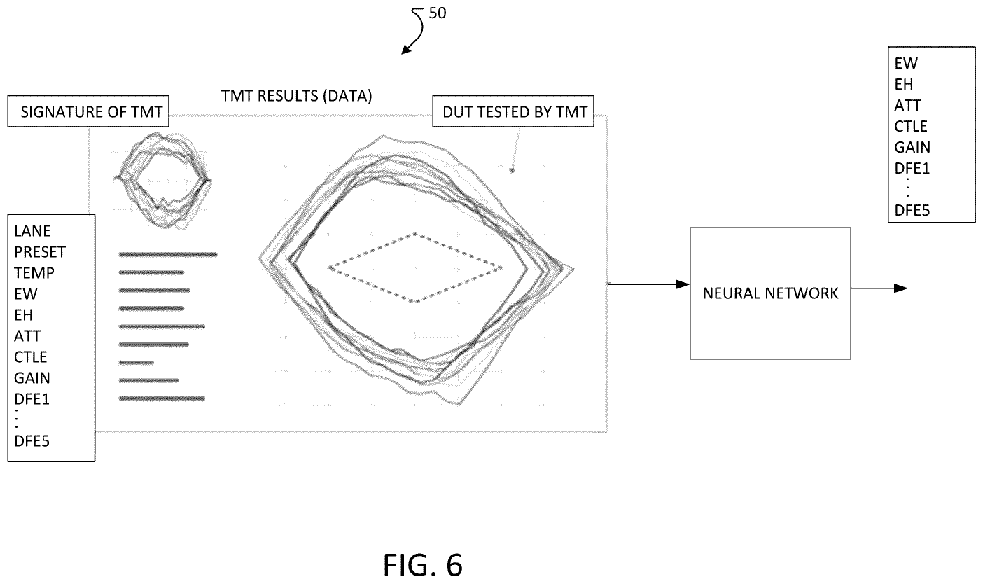

FIG. 6 shows an embodiment of the prediction of the DUT results. On the left side, the data provided to the neural network 50 would be the same types of data as provided during training. In this environment though, the neural network would provide the prediction of one or more of the measurements. The neural network could also be configured to produce a pass/fail result as the performance measurement prediction as well.

The above discussion, while general to all DUTs, mostly discussed the configuration of the setup for a transmitter test. In the case of the transmitter test, the receiver of the TMT receives signals from the lanes being used by the DUT and the received signals are used to generate the contours and other measurements. As will be discussed below, the TMT could also be used to perform a receiver test. In this instance, the TMT will also send the signals to the DUT.

Characterization of receivers involves generating a signal that has a desired stress level. In traditional testing, a scope, such as a real-time scope, calibrates the BERT to generate the output signal with the desired stress. The BERT output is then connected to the DUT receiver. Using the TMT as the signal generator improves the test throughput since the TMT has much higher channel counts. One can configure the TMT Tx to generate signals with various stress. The transmitter settings may include the Tx FFE (feedforward equalizer) setting, and gain settings, among many others. Tuning the Tx FFE taps results in various conditions such as pre-shoot as an example. The scope then provides labels of the training data, which is the stress levels. The labels include random jitter, periodic jitter, total jitter, vertical noise, intersymbol interference (ISI), and others.

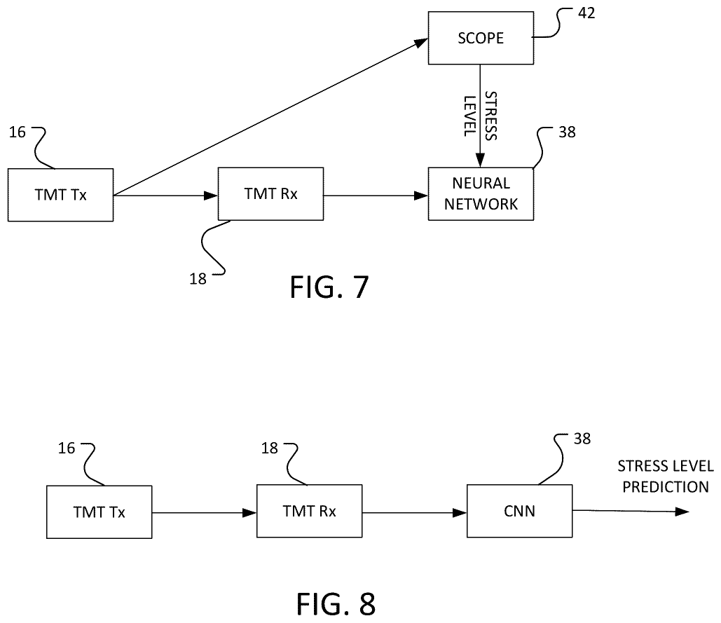

FIG. 7 shows a training configuration in abbreviated form. The scope 42 is part of the reference test station 40 of previous figures. The TMT Tx generates the signal having the desired stress and sends it to the receiver 18, and the scope 42. The receiver sends its results, such as contours, to the neural network 38 with the labels provided by the scope for the training data.

During runtime, one may consider two cases for the receiver test. In a first case, the neural network, external to the TMT receiver, receives the contours from the TXT receiver and makes the prediction of receiver stress. FIG. 8 shows an embodiment of this example. The TMT Tx 16 sends the test signal to the TMT Rx 18, which in turn sends the contours it generated through scanning to the neural network 38. The neural network determines the stress levels in the signal.

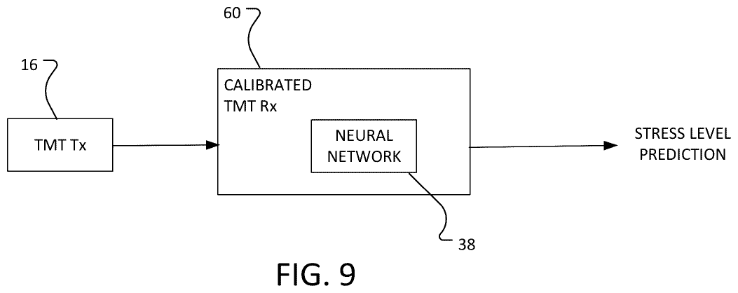

In another embodiment, as shown in FIG. 9 and as discussed above, the TMT Rx may be “calibrated” in that it has a trained neural network within it. The TMT 60 may include the trained neural network, and in other embodiments, may also undergo training. However, in the embodiment of FIG. 9, the TMT Tx 16 sends signals to the calibrated TMT 60 having a receiver, which contains the trained neural network. The neural network within the TMT then detects the stress level.

As a variation, the system may use more than one neural network. For example, one neural network could undergo training to predict the transmitter measurements, and one neural network could undergo training to predict stress levels for receiving testing. The training setup would be the same, the networks would just receive a subset of the information used to train a single neural network.

The embodiments above use machine learning to predict the performance of the DUT. One embodiment has a transmitter as the DUT, and another has a receiver as the DUT. and the machine learning system provides a prediction of the DUT performance based upon the inputs as a performance indicator to the neural network. The neural network then provides a prediction of measurements of the DUT performance. Using the margin tester allows the DUT to be tested using multiple lanes simultaneously. In one experiment, the results were obtained using the margin tester in a minute or less. This speeds up the text process, and the use of the TMT signature allows the neural network to “calibrate” based on the inputs that include the TMT signature to alleviate issues with variances between TMT devices.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

The previously described versions of the disclosed subject matter have many advantages that were either described or would be apparent to a person of ordinary skill. Even so, these advantages or features are not required in all versions of the disclosed apparatus, systems, or methods.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### Examples

Illustrative examples of the disclosed technologies are provided below. An embodiment of the technologies may include one or more, and any combination of, the examples described below.

Example 11 is a margin tester, comprising: one or more ports to allow the margin tester to connect to a device under test (DUT); a memory, the memory containing a margin tester signature; a transmitter; a receiver to receive signals from the DUT; one or more processors configured to execute code that causes the one or more processors to: receive multiple signals from the receiver through the one or more ports; generate a performance indicator from the multiple signals; send the performance indicator and the margin tester signature to one or more machine learning networks; and receiving a result from the one or more machine learning networks containing a performance measurement prediction for the DUT.

Example 2 is the margin tester of Example 1, wherein the DUT comprises a transmitter, and one or more of the multiple signals from the receiver comprises a performance indicator generated from reception of a transmission from the transmitter.

Example 3 is the margin tester of Example 2, wherein the code that causes the one or more processors to send the performance indicator and the margin tester signature to one or more machine learning networks comprises code that causes the one or more processors to send parameters and settings for the transmitter to the one or more machine learning networks.

Example 4 is the margin tester of Example 2, wherein the code that causes the one or more processors to generate the performance indicator comprises code that causes the one or more processors to generate bit error ratio (BER) contours.

Example 5 is the margin tester of any of Examples 1 through 4, wherein the margin tester signature comprises BER contours unique to the margin tester.

Example 6 is the margin tester of any of Examples 1 through 5, wherein the performance measurement prediction comprises one or either a pass/fail prediction, or one or more measurements.

Example 7 is the margin tester of any of Examples 1 through 6, wherein the code that causes the one or more processors to send the performance indicator to the machine learning network comprises code to cause the one or more processors to build a tensor image of the performance indicator and send the tensor image to the machine learning network.

Example 8 is the margin tester of Example 7, wherein the tensor image includes one or more of configuration parameters for one or more channels of the DUT, environmental parameters, and measurement results.

Example 9 is the margin tester of Example 1, wherein the DUT being tested comprises the receiver and the signal received from the DUT comprise a signal received by the receiver.

Example 10 is the margin tester of any of Examples 1 through X, wherein the signal received by the receiver is generated by the margin tester transmitter.

Example 11 is the margin tester of either of Examples 9 or 10, wherein the code that causes the one or more processors to generate a performance indicator from the signal comprises code that causes the one or more processors to generate BER contour scans of the signal.

Example 12 is the margin tester of any of Examples 1 through 11, wherein the code that causes the one or more processors to send the performance indicator and the margin tester signature to the one or more machine learning networks comprises code that causes the one or more processors to send the performance indicator and the margin tester signature to one or more external neural networks.

Example 13 is the margin tester of any of Examples 1 through 12, wherein the code that causes the one or more processors to send the performance indicator and the margin tester signature to the one or more machine learning networks comprises code that causes the one or more processors to send the performance indicator and the margin tester signature to one or more neural networks residing on the margin tester.

Example 14 is a method, comprising: receiving multiple signals from a device under test (DUT) at a receiver of a margin tester, the margin tester having a margin tester signature; generating a performance indicator from the multiple signals; sending the performance indicator and the margin tester signature to one or more machine learning networks; and receiving a result from the one or more machine networks containing a performance measurement prediction for the DUT.

Example 15 is the method of Example 14, wherein the DUT comprises a transmitter.

Example 16 is the method of Example 15, further comprising training the one or more neural networks, the training comprising: collecting performance indicators for a number of margin testers; and labeling the performance indicators for each margin tester with the margin tester signature and one or more of configuration of a transmitter channel, environment parameters, and raw measurement results.

Example 17 is the method of Example 14, wherein the DUT comprises a receiver.

Example 18 is the method of Example 17, further comprising training the one or more neural networks, the training comprising: collecting performance indicators for a number of margin testers; and labeling the performance indicators for each margin tester with the margin tester signature and stress applied to the multiple signals before the multiple signals were transmitted.

Example 19 is the method of any of Examples 14 through 18, wherein the performance measurement prediction comprises one or either a pass/fail prediction, or one or more measurement predictions for the DUT.

Example 20 is the method of any of Examples 14 through 19, wherein sending the performance indicator and the margin tester signature to the one or more machine learning networks comprises sending the performance indicator and the margin tester signature to either one of one or more neural networks external to the margin tester, or one or more neural networks residing in the margin tester.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific examples of the invention have been illustrated and described for purposes of illustration, it will be understood that various modifications may be made without departing from the spirit and scope of the invention. Accordingly, the invention should not be limited except as by the appended claims.

1. A margin tester, comprising:
one or more ports to allow the margin tester to connect to a device under test (DUT);
a memory, the memory containing a margin tester signature;
a transmitter;
a receiver to receive signals from the DUT;
one or more processors configured to execute code that causes the one or more processors to:
receive multiple signals from the receiver through the one or more ports;
generate a performance indicator from the multiple signals;
send the performance indicator and the margin tester signature to one or more machine learning networks; and
receive a result from the one or more machine learning networks containing a performance measurement prediction for the DUT.

2. The margin tester as claimed in claim 1, wherein the DUT comprises a transmitter, and one or more of the multiple signals from the receiver comprises a performance indicator generated from reception of a transmission from the transmitter.

3. The margin tester as claimed in claim 2, wherein the code that causes the one or more processors to send the performance indicator and the margin tester signature to one or more machine learning networks comprises code that causes the one or more processors to send parameters and settings for the transmitter to the one or more machine learning networks.

4. The margin tester as claimed in claim 2, wherein the code that causes the one or more processors to generate the performance indicator comprises code that causes the one or more processors to generate bit error ratio (BER) contours.

5. The margin tester as claimed in claim 1, wherein the margin tester signature comprises BER contours unique to the margin tester.

6. The margin tester as claimed in claim 1, wherein the performance measurement prediction comprises one or either a pass/fail prediction, or one or more measurements.

7. The margin tester as claimed in claim 1, wherein the code that causes the one or more processors to send the performance indicator to the machine learning network comprises code to cause the one or more processors to build a tensor image of the performance indicator and send the tensor image to the machine learning network.

8. The margin tester as claimed in claim 7, wherein the tensor image includes one or more of configuration parameters for one or more channels of the DUT, environmental parameters, and measurement results.

9. The margin tester as claimed in claim 1, wherein the DUT being tested comprises the receiver and the signal received from the DUT comprise a signal received by the receiver.

10. The margin tester as claimed in claim 9, wherein the signal received by the receiver is generated by the margin tester transmitter.

11. The margin tester as claimed in claim 9, wherein the code that causes the one or more processors to generate a performance indicator from the signal comprises code that causes the one or more processors to generate BER contour scans of the signal.

12. The margin tester as claimed claim 1, wherein the code that causes the one or more processors to send the performance indicator and the margin tester signature to the one or more machine learning networks comprises code that causes the one or more processors to send the performance indicator and the margin tester signature to one or more external neural networks.

13. The margin tester as claimed claim 1, wherein the code that causes the one or more processors to send the performance indicator and the margin tester signature to the one or more machine learning networks comprises code that causes the one or more processors to send the performance indicator and the margin tester signature to one or more neural networks residing on the margin tester.

14. A method, comprising:
receiving multiple signals from a device under test (DUT) at a receiver of a margin tester, the margin tester having a margin tester signature;
generating a performance indicator from the multiple signals;
sending the performance indicator and the margin tester signature to one or more machine learning networks; and
receiving a result from the one or more machine networks containing a performance measurement prediction for the DUT.

15. The method as claimed in claim 14, wherein the DUT comprises a transmitter.

16. The method as claimed in claim 15, further comprising training the one or more neural networks, the training comprising:
collecting performance indicators for a number of margin testers; and
labeling the performance indicators for each margin tester with the margin tester signature and one or more of configuration of a transmitter channel, environment parameters, and raw measurement results.

17. The method as claimed in claim 14, wherein the DUT comprises a receiver.

18. The method as claimed in claim 17, further comprising training the one or more neural networks, the training comprising:
collecting performance indicators for a number of margin testers; and
labeling the performance indicators for each margin tester with the margin tester signature and stress applied to the multiple signals before the multiple signals were transmitted.

19. The method as claimed in claim 14, wherein the performance measurement prediction comprises one or either a pass/fail prediction, or one or more measurement predictions for the DUT.

20. The method as claimed in claim 14, wherein sending the performance indicator and the margin tester signature to the one or more machine learning networks comprises sending the performance indicator and the margin tester signature to either one of one or more neural networks external to the margin tester, or one or more neural networks residing in the margin tester.
